(19) United States
(12) Patent Application Publication
(10) Pub. No.: US 2025/0253119 A1
(43) Pub. Date: Aug. 7, 2025

(54) ION IMPLANTATION APPARATUS

(71) Applicant: NISSIN ION EQUIPMENT CO, LTD., Koka-city (JP)

(72) Inventor: Yuya HIRAI, Koka- city (JP)

(73) Assignee: NISSIN ION EQUIPMENT CO, LTD., Koka-city (JP)

(21) Appl. No.: 18/976,436

(22) Filed: Dec. 11, 2024

(30) Foreign Application Priority Data
Feb. 7, 2024 (JP) 2024-016966

(51) Int. Cl. H01J 37/20; H01J 37/304; H01J 37/317; H01L 21/67; H01L 21/68

(52) U.S. Cl. CPC H01J 37/20; H01J 37/3045; H01J 37/3171; H01L 21/67196; H01L 21/67213; H01L 21/68; H01J 2237/2007

(57) ABSTRACT

An ion implantation apparatus for performing channeling ion implantation into a wafer after measuring a crystal orientation of the wafer and adjusting an inclination of the wafer based on a result of the crystal orientation measurement includes a transfer portion that is provided with a measurement position for measuring the crystal orientation of the wafer, the measurement position being between a first position and a second position on a transport path of the wafer, the transfer portion transporting the wafer in order from the first position, to the measurement position, to the second position in an ion implantation process on the wafer, and a controller that controls the transfer portion to transfer the wafer. The controller controls the transfer portion to start to move the wafer from the measurement position towards the second position before a crystal orientation measurement result of the wafer is output.

### CROSS-REFERENCE TO RELATED APPLICATION

This application claims priority from Japanese Patent Application No. 2024-016966, filed on Feb. 7, 2024, in the Japan Patent Office, the contents of which being incorporated by reference herein in its entirety.

### BACKGROUND

The present disclosure relates to an ion implantation apparatus.

An ion implantation process from a wafer surface to a deeper region of the wafer is performed by using a channeling phenomenon. Specifically, an irradiation angle of an ion beam to the wafer surface is adjusted, a crystal axis of the wafer and an irradiation direction of the ion beam are aligned, and the ion implantation process is performed on the wafer to implant ions in the deeper region of the wafer. This ion implantation process is called channeling ion implantation.

### SUMMARY

According to an aspect of one or more embodiments, there is provided an ion implantation apparatus for performing channeling ion implantation into a wafer after measuring a crystal orientation of the wafer and adjusting an inclination of the wafer based on a result of the crystal orientation measurement, the ion implantation apparatus comprising a transfer portion that is provided with a measurement position for measuring the crystal orientation of the wafer, the measurement position being between a first position and a second position on a transport path of the wafer, the transfer portion transporting the wafer in order from the first position, to the measurement position, to the second position in an ion implantation process on the wafer; and a controller that is configured to control the transfer portion to transfer the wafer.

The controller controls the transfer portion to start to move the wafer from the measurement position towards the second position before a crystal orientation measurement result of the wafer is output.

According to another aspect of one or more embodiments, there is provided an ion implantation apparatus comprising a process chamber including a platen; a plurality of vacuum hands respectively having a plurality of gripping portions at distal ends of the vacuum hands; and a plurality of loadlock chambers; a chamber including a plurality of atmospheric robots; and a plurality of cassettes; and a controller that is configured to control the plurality of atmospheric robots, the plurality of loadlock chambers and the plurality of vacuum hands to transfer a wafer from one of the plurality of cassettes to a crystal orientation measurement position that is in the ion implantation apparatus on a transfer path between the one of the cassettes and the platen, and to start to move the wafer from the crystal orientation measurement position towards the platen before a crystal orientation measurement result of the wafer is output.

According to yet another aspect of one or more embodiments, there is provided an ion implantation apparatus comprising a process chamber including a platen; a plurality of vacuum hands respectively having a plurality of gripping portions at distal ends of the vacuum hands; and a plurality of loadlock chambers; a chamber including an aligner that is configured to adjust a position of a wafer and a plurality of atmospheric robots; a plurality of cassettes; a transfer portion that includes one of the atmospheric robots, one of the loadlock chambers, and one of the vacuum hands, the transfer portion being configured to transfer a wafer along a transport path from one of the cassettes, to the aligner, and to the platen; and a controller that is configured to control a crystal orientation measurement device to measure a crystal orientation of a wafer at the aligner and to control the transfer portion to start to move the wafer from the aligner towards the platen before a crystal orientation measurement result of the wafer is output from the crystal orientation measurement device.

### BRIEF DESCRIPTION OF THE DRAWINGS

The above and/or other aspects will become apparent and more readily appreciated from the following description of various embodiments, taken in conjunction with the accompanying drawings, in which:

FIG. 1 is a schematic plan view of an example configuration of a periphery of a process chamber of an ion implantation apparatus, according to some embodiments;

FIG. 2 is an explanatory view of a posture of a platen at a time of wafer transfer, according to some embodiments;

FIG. 3 is an explanatory view of a posture of a platen during an ion implantation process, according to some embodiments;

FIG. 4 is a time chart showing an example of wafer transfer, according to some embodiments;

FIG. 5 is a time chart showing an example of wafer transfer, according to some embodiments;

FIG. 6 is a time chart showing an example of wafer transfer, according to some embodiments; and

FIG. 7 is a flowchart showing an example of a wafer transfer process, according to some embodiments.

### DETAILED DESCRIPTION

In a wafer manufacturing process, for example, a slicing process and/or a polishing process, a manufacturing error occurs in a wafer thickness. Here, the wafer thickness denotes a thickness from a first surface of the wafer to a second surface of the wafer opposite from the first surface. Due to the influence of the manufacturing error, a crystal axis direction (i.e., crystal orientation) of a wafer may be inclined by several degrees from a direction perpendicular to the wafer surface. Depending on the degree of the manufacturing error, even if an irradiation angle of an ion beam to the wafer surface is correctly adjusted, it is impossible to realize a desired ion implantation process.

In addition, in an epitaxial wafer of silicon carbide in which an epitaxial layer is formed on a wafer serving as a base (i.e., a base wafer), an offset angle of about 4 degrees is set. The reason why the offset angle is set is to avoid the influence of defects in the epitaxial layer. The base wafer having the set offset angle is manufactured by obliquely cutting an ingot in a slicing step. Therefore, the wafer surface and the crystal plane of the wafer do not coincide with each other, and, in this case, even if there is no manufacturing error of the wafer, the crystal axis direction may not be necessarily perpendicular to the wafer surface.

Therefore, in performing the channeling ion implantation, a measurement of the crystal orientation of the wafer may be performed. In a related art technology, a crystal orientation measurement device is disposed inside the ion implantation apparatus, causing some disadvantages.

Although the measurement of the crystal orientation may depend, in part, on a kind of crystal orientation measurement device used, regardless of the type of crystal orientation measurement device used, it takes several tens of seconds to several minutes to output a measurement result of the crystal orientation. When the crystal orientation measurement device is disposed inside the ion implantation apparatus, a time from a time at which the wafer to be processed is take out from the cassette to a time at which the implantation process is performed on the wafer becomes long. This increased time reduces a productivity of the ion implantation apparatus. Various embodiments described herein address these disadvantages with the related art technology.

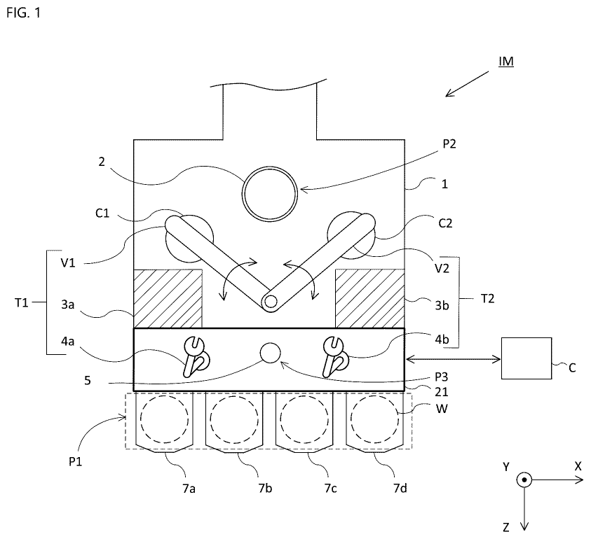

FIG. 1 is a schematic plan view of an example configuration of a periphery of a process chamber 1 of an ion implantation apparatus IM.

In some embodiments, the ion implantation apparatus IM may include the process chamber 1, a chamber 21, and a plurality of cassettes 7a to 7d. In some embodiments, the ion implantation apparatus IM may further include a controller C. In some embodiments, the controller C may include a processor and a memory. The processor may be a microprocessor, a central processing unit (CPU), a microcontroller, or hardware control logic, or some combination thereof. In some embodiments, the processor may be provided as a plurality of processors. In some embodiments, the process chamber 1 may include a platen 2, a plurality of vacuum hands V1 and V2, a plurality of gripping portions C1 and C2, and a plurality of loadlock chambers 3a and 3b. In some embodiments, the chamber 21 may include an aligner 5 and a plurality of atmospheric robots 4a and 4b. A plurality of wafers W are stored in the plurality of cassettes 7a to 7d, respectively. One of atmospheric robots 4a and 4b takes out the wafer W from one of the cassettes 7a to 7d and transfers the wafer W to the aligner 5. After a circumferential position of the wafer W is adjusted by the aligner 5, one of the atmospheric robots 4a and 4b transfers the wafer W to one of loadlock chambers 3a and 3b.

The process chamber 1 is held in a vacuum, and the chamber 21 is held at atmospheric pressure. The loadlock chambers 3a and 3b can transfer the wafer W between the process chamber 1 and the chamber 21, which have different vacuum degrees. In other words, the loadlock chambers 3a and 3b provide a function of changing a vacuum degree between the process chamber 1 and the chamber 21. In some embodiments, a pressure inside each of the loadlock chambers 3a and 3b may be changed.

Each of the loadlock chambers 3a and 3b has a floor which moves along a Y direction in the FIG. 1 by a driving mechanism (not shown). The movement of the floor is performed after an inside of the loadlock chamber 3a and 3b is changed from the atmosphere pressure to the vacuum or from the vacuum to the atmosphere pressure.

The vacuum hand V1 and a V2 can independently rotate in a direction of an arrow shown in the FIG. 1. The vacuum hands V1 and V2 include the gripping portions C1 and C2 respectively disposed at distal ends thereof for gripping a periphery of the wafer W. In some embodiments, one of the vacuum hands V1 and V2 may pick up the wafer W from one of the loadlock chambers 3a and 3b and transfer the wafer W to the platen 2.

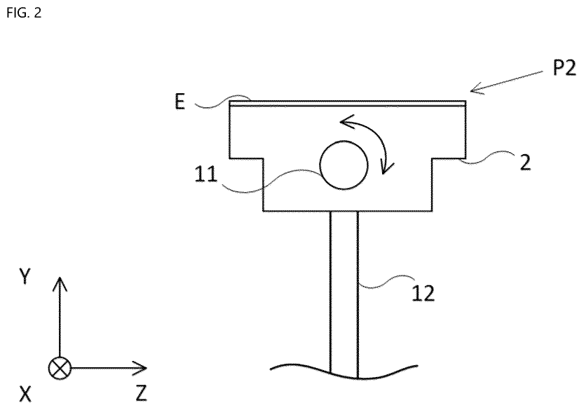

When the wafer W is transferred from the vacuum hand V1 or V2 to the platen 2, the platen 2 is in a horizontal state as shown in FIG. 2.

The platen 2 includes an electrostatic chuck E for holding the wafer W. After the wafer W is fixed to the platen 2 by the electrostatic chuck E, the posture of the platen 2 may be adjusted by a tilt mechanism 11 and a twist mechanism (not shown). In some embodiments, the tilt mechanism 11 and/or the twist mechanism may be implemented by one or more motors, gears, belts, etc.

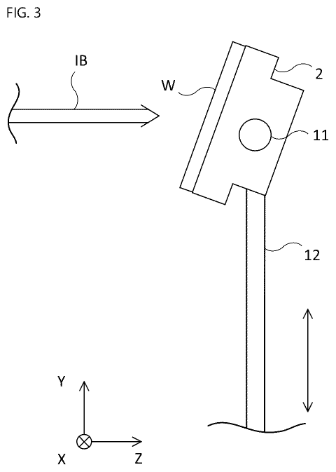

The tilt mechanism 11 shown in FIG. 2 and FIG. 3 is a mechanism for adjusting the tilt of the platen 2 about the X axis as a rotation axis. The twist mechanism (not shown) is a mechanism for adjusting the position of the wafer W in the circumferential direction by rotating the platen 2. In some embodiments, the rotation axis of the tilt mechanism 11 may be the Y axis instead of the X axis. In some embodiments, the rotation axis of the tilt mechanism 11 may be both the X axis and the Y axis.

A drive shaft 12 is attached to the platen 2, and the drive shaft 12 moves the platen 2 in the Y-axis direction by a drive motor (not shown). The ion beam IB in FIG. 3 is an ion beam having a spot-like cross section in the XY plane. The scanning of the ion beam is performed in the X-axis direction by an electrostatic field or a magnetic field. In some embodiments, the scanning width may be set to be equal to or larger than the diameter of the wafer W.

As shown in FIG. 3, after the posture of the platen 2 is adjusted, the surface to be processed of the wafer W is moved across the ion beam IB by the movement of the drive shaft 12. Thus, the ion implantation process is performed on the wafer W.

In some embodiments, instead of the ion beam IB described above with respect to FIG. 3, a ribbon-shaped ion beam having a substantially rectangular shape which is long in the X-axis direction and short in the Y-axis direction in a cross section in the XY plane may be used.

The configuration of the ion implantation apparatus IM described with reference to FIGS. 1 to 3 is an example. The numbers of the plurality of vacuum hands V1 and V2, the plurality of loadlock chambers 3a and 3b, the plurality of atmospheric robots 4a and 4b, and the plurality of cassettes 7a to 7d are not limited to those shown in FIG. 1, and, in some embodiments, a configuration in which one of each is provided may be adopted. In some embodiments, more than two of each of the plurality of vacuum hands V1 and V2, the plurality of loadlock chambers 3a and 3b, the plurality of atmospheric robots 4a and 4b may be provided, and more than four of the plurality of cassettes 7a to 7d may be provided.

The controller C is a device that controls each portion of the ion implantation apparatus IM, and includes functions for controlling each portion, such as a calculation part and a storage part. For example, the calculation part may be implemented by the processor and the storage part may be implemented by the memory, as described above. For example, the controller C may control the plurality of vacuum hands V1 and V2, the plurality of loadlock chambers 3a and 3b, the plurality of atmospheric robots 4a and 4b. In some embodiments, the controller C may control the pressure in the loadlock chambers 3a and 3b and the process chamber 1. In some embodiments, the controller C may control a motor implementing the tilt mechanism 11, a motor implementing the twist mechanism, a motor moving the drive shaft 12, and/or the electrostatic chuck E. In some embodiments, the controller C may be hardware control logic configured to control the plurality of vacuum hands V1 and V2, the plurality of loadlock chambers 3a and 3b, the plurality of atmospheric robots 4a and 4b, the pressure in the loadlock chambers 3a and 3b and the process chamber 1, the motor implementing the tilt mechanism 11, the motor implementing the twist mechanism, the motor moving the drive shaft 12, and/or the electrostatic chuck E. As described above, in some embodiments, the controller C may include the processor, such as a microprocessor, a microcontroller, an ASIC, etc., and the processor may be configured to access program code stored in the memory and execute the program code to cause the processor to control the plurality of vacuum hands V1 and V2, the plurality of loadlock chambers 3a and 3b, the plurality of atmospheric robots 4a and 4b, the pressure in the loadlock chambers 3a and 3b and the process chamber 1, the motor implementing the tilt mechanism 11, the motor implementing the twist mechanism, the motor moving the drive shaft 12, and/or the electrostatic chuck E. In some embodiments, the program code may include separate program code for controlling each of the plurality of vacuum hands V1 and V2, the plurality of loadlock chambers 3a and 3b, the plurality of atmospheric robots 4a and 4b, the pressure in the loadlock chambers 3a and 3b and the process chamber 1, the motor implementing the tilt mechanism 11, the motor implementing the twist mechanism, the motor moving the drive shaft 12, and/or the electrostatic chuck E. In some embodiments, the same program code may cause the processor to control the plurality of vacuum hands V1 and V2, the plurality of loadlock chambers 3a and 3b, the plurality of atmospheric robots 4a and 4b, the pressure in the loadlock chambers 3a and 3b and the process chamber 1, the motor implementing the tilt mechanism 11, the motor implementing the twist mechanism, the motor moving the drive shaft 12, and/or the electrostatic chuck E.

In an embodiment, the crystal orientation measurement of the wafer W is performed, for example, at a position where the aligner 5 is disposed. When the arrangement position of the aligner 5 is set as a measurement position P3, the aligner 5 can be used also as a support table of the wafer W at the time of crystal orientation measurement. Further, the position of the wafer W in the circumferential direction can be adjusted for the crystal orientation measurement by using the rotation mechanism of the aligner 5.

In this way, since the crystal orientation measurement device can use part of the configuration and functions of the aligner 5, the configuration of the crystal orientation measurement device can be simplified.

In some embodiment, the crystal orientation measurement device may include an X-ray diffraction apparatus. As a measurement method, a measurement method of detecting reflected light or transmitted light from the wafer at a plurality of points by changing the position of a detector or a measurement method of detecting reflected or transmitted light from the wafer by a two-dimensional detector fixed in a position can be used.

A flatness of the surface of the wafer W to be measured is not necessarily constant. For example, the flatness may be slightly different from wafer to wafer, and some types of wafers W may have a large warpage. When the crystal orientation measurement is performed for the wafer W having a large warpage, there is a concern that the crystal axis direction cannot be correctly measured. Even if the measurement is possible, if there is a large difference in the flatness of the wafer W between when the crystal orientation measurement is performed and when the ion implantation is performed, accurate channeling ion implantation is difficult.

As a countermeasure, an electrostatic chuck may be provided on a measurement table on which the wafer W is placed, and the wafer W may be chucked by the electrostatic chuck, whereby the crystal orientation of the wafer may be measured in a state where the warpage of the wafer W is improved. In some embodiments, instead of the electrostatic chuck, a vacuum chuck may be used.

When the measurement table is provided with the electrostatic chuck or the vacuum chuck, the attraction force of the electrostatic chuck or the vacuum chuck at the time of crystal orientation measurement may be the same as at the time at which an ion implantation process is performed. Thus, the warpage of the wafer W attracted to the electrostatic chuck or the vacuum chuck can be corrected to the same degree, and therefore, the crystal orientation and the irradiation angle of the ion beam can be matched with higher accuracy.

In some embodiments, the crystal orientation device may include a device that does not use X-rays. For example, the device may use light emitted from a mercury lamp, a halogen lamp, or a helium-neon laser and may apply the light to the wafer W through an optical element such as a wavelength plate or a polarizing plate. A crystal orientation measurement device that measures reflected light from the wafer W or transmitted light that has passed through the wafer W and specifies the crystal orientation direction from the intensity of the measured light is exemplified.

Positions sandwiching the measurement position P3 in a transfer path of the wafer W from the cassettes 7a to 7d in which the wafer W is stored to the platen 2 in which the implantation posture of the wafer W is adjusted are defined as a first position P1 and a second position P2. In other words, the first position P1 and the second positon P2 may be provided on respectively sides of the third position P3 as illustrated in FIG. 1.

In the configuration examples of FIG. 1 and FIG. 2, the first position P1 is the arrangement position of the cassettes 7a to 7d, and the second position P2 is the arrangement position of the platen 2.

A portion of the ion implantation apparatus IM for transferring the wafer W from the first position P1 to the second position P2 through the measurement position P3 is referred to as a transfer portion. In the configuration example of FIG. 1, the ion implantation apparatus IM has two transfer portions T1 and T2. The transfer portion T1 includes the atmospheric robot 4a, the loadlock chamber 3a, and a vacuum hand V1. The transfer portion T2 includes the atmospheric robot 4b, the loadlock chamber 3b, and a vacuum hand V2. For example, the controller C may select whether to use the transport portion T1 or the transport portion T2 depending on the location of the cassettes 7a to 7d from which the wafer W is to be taken.

The configuration of the transport portions T1 and T2 illustrated in FIG. 1 is an example. For example, when the wafer W is transferred in the order of the atmospheric robot 4a, the aligner 5, the atmospheric robot 4b, the loadlock chamber 3b, the vacuum hand V2, and the platen 2, the transfer portion may include the atmospheric robot 4a, the atmospheric robot 4b, the loadlock chamber 3b, and the vacuum hand V2. In other words, the transfer portion includes the components of the ion implantation apparatus IM that are used to transport the wafer along a transport path from the first position P1 to the second position P2 through the third position P3, or the components of the ion implantation apparatus IM that are used to transport the wafer along a transport path from the second position P2 to the first position P1 through the third position P3.

From the description above, it will be understood that a configuration of the transport portion may be modified according to each position of the first position P1, the measurement position P3, and the second position P2 on the transport path.

After the wafer W is transferred from the first position P1 to the measurement position P3, the crystal orientation measurement is performed at the position P3. After the measurement of the crystal orientation of the wafer W, transferring the wafer W from the measurement position P3 to the second position P2 starts before the measurement result is output.

Since the wafer W is transferred from the third position P3 to the second positon P2 by using the waiting time until the measurement result is output (e.g., while the crystal orientation is being determined/computed), the transfer time of the wafer W can be shortened as compared with a configuration of the related art technology in which the transfer of the wafer W is started after the measurement result is output.

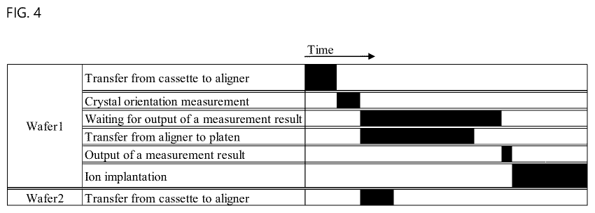

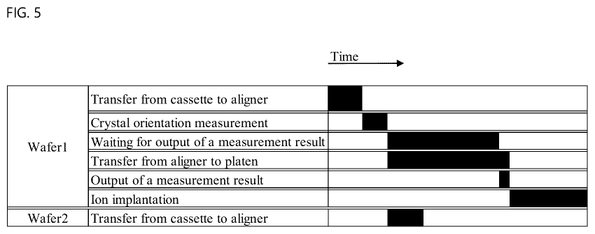

FIGS. 4 and 5 are time charts for an example of the transfer of the wafer W. Here, the first position P1 is the arrangement position of the cassettes 7a to 7d, and the second position P2 is the arrangement position of the platen 2. The measurement position P3 is the position where the aligner 5 is disposed.

In FIG. 4, the time until the measurement result of the crystal orientation measurement is output is longer than the time for transferring the wafer W from the measurement position P3 to the platen 2. The wafer W that has reached the platen 2 is on standby on the platen 2 until the measurement result is output. After the measurement result is output, the tilt angle of the platen 2 is adjusted by the tilt mechanism 11 in accordance with the crystal orientation measurement result, and the ion implantation process is performed.

In order to start the implantation process at an early stage, the standby position of the wafer W is advantageously within the process chamber 1. When the standby position of the wafer W is set to the platen 2, the time until the implantation process is started becomes the shortest.

The process chamber 1 includes the loadlock chambers 3a and 3b after the atmospheric pressure in the chamber is changed to the same vacuum degree as the process chamber 1.

In the case of considering the transfer time of the wafer W in the transfer path of the wafer W after the measurement position P3 (e.g., from the measurement position P3 to the second position P2), the time for changing the pressures in the loadlock chambers 3a and 3b from the atmospheric pressure to the vacuum pressure is relatively long. Therefore, the standby position of the wafer W is advantageously set in the process chamber 1 which is a place after the pressure changing operation in the loadlock chambers 3a and 3b. In other words, since the second positon P2 is located within the transfer path after the position of the loadlock chambers 3a and 3b, the pressure may be changed in the loadlock chambers 3a and/or 3b while waiting for the measurement result from the crystal orientation measurement.

In the single-wafer type ion implantation apparatus, the ion implantation process is performed on the wafers W one by one. As in the configuration example of FIG. 4, before the measurement result of the wafer W on which the crystal orientation measurement has been performed is output, the transfer of another wafer W (wafer 2) on which the ion implantation process will be performed next from the first position P1 (arrangement position of the cassettes 7a to 7d) to the measurement position P3 (arrangement position of the aligner 5) is started.

By transferring the wafer W (wafer 2) to be measured next to the measurement position P3 in advance, the crystal orientation measurement can be started early, and thus the time until the implantation process on the wafer W is started can be shortened.

In FIG. 5, the time from the end of the crystal orientation measurement to the output of the measurement result is shorter than the transfer time from the measurement position P3 (the position where the aligner 5 is disposed) to the second position P2 (the position where the platen 2 is disposed). The measurement result is output before the wafer W reaches the platen 2. When the wafer W reaches the platen 2, the tilt angle of the platen 2 may be immediately adjusted based on the measurement result, and the ion implantation process is performed.

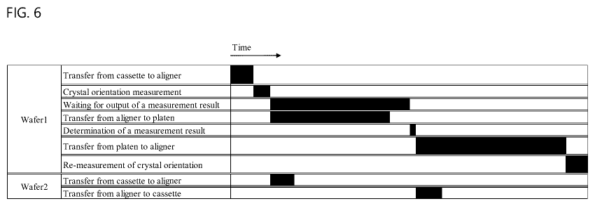

The ion implantation apparatus IM may have an interlock function based on the measurement result of the crystal orientation of the wafer W. In the time chart shown in FIG. 6, it is determined whether or not the crystal orientation measurement result is normal. This determination is made, for example, by determining whether or not the angle of the crystal orientation that has been measured exceeds a set allowable threshold range. Specifically, in an embodiment, a reference angle may be set to 4°, and the allowable threshold range may be set to +/−0.5. When the measurement result of 4.7° is output, it is determined that the measurement result includes an error.

The error described above may be mainly caused by a positional deviation of the crystal orientation measurement device. The cause of the positional deviation includes an erroneous arrangement of the crystal orientation measurement device, a collision with the crystal orientation measurement device during maintenance of the ion implantation apparatus IM, and the like.

In the configuration example of FIG. 6, when it is determined that there is an error in the measurement result, the wafer W (wafer 1) is transferred from the platen 2 to one of the cassettes 7a-7d, and the wafer W (wafer 1) is recovered. Thereafter, the operator of the ion implantation apparatus IM adjusts the position of the crystal orientation measurement device.

If another wafer W (wafer 2) is placed at the measurement position P3, the crystal orientation of the wafer W (wafer 1) cannot be measured again after the wafer W (wafer 1) is recovered. Therefore, when the measurement result is determined, another wafer W (wafer 2) placed in the aligner 5, is recovered in one of the cassettes 7a-7d.

If there is some error in the measurement process, the wafer W (wafer 1) may be returned from the position of the platen 2 to the position of the aligner 5 and the crystal orientation measurement may be performed again because the cause of the error may have been removed at the time of re-measurement.

In this case, the wafer W is transferred to the position of the aligner 5, and at the same time, another wafer W (wafer 2) disposed at the position of the aligner 5, is recovered in one of the cassettes 7a-7d.

In order to detect such an error in measurement result, the measurement result may be determined every time the crystal orientation of the wafer W is measured. However, since the misalignment of the crystal orientation measurement device is the main cause of the error, then measuring wafer W immediately after the ion implantation process begins can detect whether the measurement result contains errors.

Therefore, in an embodiment, the measurement result may be determined only when the crystal orientation of the wafer W is measured for the first time after the ion implantation apparatus IM is stopped.

When an error in the measurement result is detected, the wafer W is returned to a predetermined position, which complicates the control of the transfer of the wafer W. In order to avoid the complication of the transfer control of the wafer W, the wafer W may be kept waiting at the measurement position P3 until the measurement result is determined.

However, in the configuration in which the wafer W is on standby every time the crystal orientation measurement of the wafer W is performed, the time until the implantation process of the wafer W is started cannot be shortened. Therefore, the wafer W may be configured to wait at the measurement position P3 only when the first wafer W is processed after the ion implantation apparatus IM is stopped.

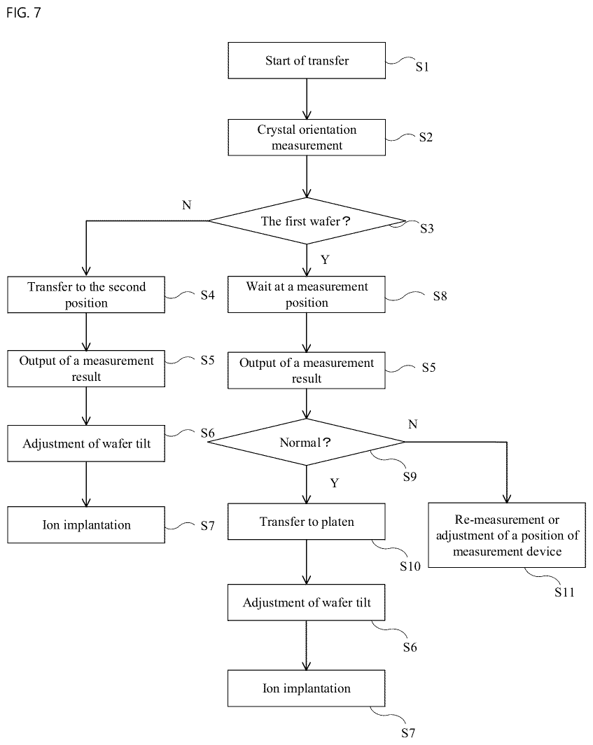

FIG. 7 is a flow chart illustrating a wafer transfer, according to some embodiments. The transfer of the wafer W is started (S1), and the crystal orientation of the wafer W is measured at the measurement position P3 (S2). Next, it is determined whether the wafer W is the first wafer W to be processed after the ion implantation apparatus IM is stopped (S3).

If the wafer W is not the first wafer W (S3, N), the wafer W is transferred to the second position P2 (S4). Thereafter, the measurement result of crystal orientation of the wafer W is output (S5), and the tilt angle of the wafer W is adjusted according to the measurement result (S6). Finally, the wafer W whose inclination has been adjusted is subjected to ion implantation (S7).

On the other hand, if the wafer W is the first wafer W to be processed after the ion implantation apparatus IM is stopped, (S3, Y) the wafer W is on standby at the measurement position P3 (S8). Thereafter, the measurement result is output (S5), and it is determined whether the crystal orientation measurement is normal or erroneous (S9).

If the crystal orientation measurement of the wafer W is determined to be normal in this determination (S9, Y), the wafer W is transferred to the platen 2 (S10), the tilt angle of the wafer W is adjusted (S6), and the ion implantation process is performed (S7). On the contrary, when the crystal orientation measurement is determined to be erroneous (S9, N), the crystal orientation measurement of the wafer W is performed again or the position adjustment of the crystal orientation measurement device is performed (S11).

In the embodiment illustrated in FIG. 7, the positional deviation of the crystal orientation measurement device is indirectly detected based on the result of the crystal orientation measurement of the wafer W. However, it may be possible to directly detect the positional deviation of the crystal orientation measurement device.

For example, in an embodiment, a light receiving/emitting sensor for optically detecting the position of the crystal orientation measurement device may be provided, and it is determined that there is a positional deviation when the crystal orientation measurement device blocks light. In some embodiments, the presence or absence of the positional deviation may be determined by measuring the displacement of the crystal orientation measurement device by a laser displacement gauge. In some embodiments, the crystal orientation measurement device may include a gyroscope and, the positional deviation of the crystal orientation measurement device may be determined by referring to the information from the gyroscope.

In the above embodiments, the control of the transfer of the wafer W and the determination of the measurement result are performed by the controller C shown in FIG. 1.

The crystal orientation measurement device may be disposed at a position other than the position of the aligner 5 inside the ion implantation apparatus IM. For example, the crystal orientation measurement device may be disposed in the process chamber 1 or at a position of one of the cassettes 7a to 7d. In an embodiment, if the crystal orientation measurement device is arranged at the position of one of cassettes 7a to 7d, the cassette is removed and the crystal orientation measurement device is arranged in place of the cassette.

The inside of the ion implantation apparatus IM includes positions on the transfer path of the wafer W from the cassettes 7a and 7d to the platen 2 where the implantation posture of the wafer W is adjusted in the ion implantation apparatus IM. In some embodiments, the crystal orientation measurement device may be attached externally to the ion implantation apparatus IM. For example, in an embodiment, one or more transfer tables, one or more transfer robots and the crystal orientation measurement device may be disposed outside the ion implantation apparatus IM. In this case, a portion of the transfer path of the wafer may be outside of the ion implantation apparatus IM. For example, in an embodiment, one of the atmospheric robots 4a, 4b may move a wafer W from one of the cassettes 7a-7d to one of the transfer tables, and one of the transfer robots may move the wafer W from the transfer table to the crystal orientation measurement device. After the crystal orientation measurement, one of the transfer robots may move the wafer W to a transfer table, and one of the atmospheric robots 4a, 4b may move the wafer W to the aligner 5 and then to one of the loadlock chambers 3a, 3b and to the platen 2, as described above. The remaining components of the ion implantation apparatus IM and their functions are similar to those described above and a repeated description thereof is omitted for conciseness. In the case in which the crystal orientation measurement device is disposed outside of the ion implantation apparatus IM, the crystal orientation measurement may be made on the transport path of the wafer W at a portion of the transport path located outside the ion implantation apparatus IM. Thus, in some embodiments, the crystal orientation measurement device may be externally attached to the ion implantation apparatus IM and the crystal orientation measurement may still be performed at a location along the transport path.

It should be understood that embodiments are not limited to the various embodiments described above with reference to the drawings, but various other changes and modifications may be made therein without departing from the spirit and scope thereof as set forth in appended claims.

What is claimed is:

1. An ion implantation apparatus for performing channeling ion implantation into a wafer after measuring a crystal orientation of the wafer and adjusting an inclination of the wafer based on a result of the crystal orientation measurement, the ion implantation apparatus comprising:
a transfer portion that is provided with a measurement position for measuring the crystal orientation of the wafer, the measurement position being between a first position and a second position on a transport path of the wafer, the transfer portion transporting the wafer in order from the first position, to the measurement position, to the second position in an ion implantation process on the wafer; and
a controller that is configured to control the transfer portion to transfer the wafer;
wherein the controller controls the transfer portion to start to move the wafer from the measurement position towards the second position before a crystal orientation measurement result of the wafer is output.

2. The ion implantation apparatus according to claim 1, wherein the transfer portion transfers another wafer to be processed next from the first position toward the measurement position before the crystal orientation measurement result of the wafer is output.

3. The ion implantation apparatus according to claim 2, further comprising an aligner that is configured to adjust a position of the wafer in a circumferential direction,
wherein the aligner is provided at the measurement position.

4. The ion implantation apparatus according to claim 3, wherein the aligner comprises an electrostatic chuck or a vacuum chuck.

5. The ion implantation apparatus according to claim 1, further comprising an aligner that is configured to adjust a position of the wafer in a circumferential direction,
wherein the aligner is provided at the measurement position.

6. The ion implantation apparatus according to claim 5, wherein the aligner comprises an electrostatic chuck or a vacuum chuck.

7. The ion implantation apparatus according to claim 1, wherein the controller controls the transfer portion to keep the wafer at the second position until the crystal orientation measurement result of the wafer is output.

8. The ion implantation apparatus according to claim 2, wherein the controller controls the transfer portion to keep the wafer at the second position until the crystal orientation measurement result of the wafer is output.

9. The ion implantation apparatus according to claim 1, wherein controller controls the transfer portion to transfer the wafer to the measurement position or to the first position, based on the crystal orientation measurement result of the wafer.

10. The ion implantation apparatus according to claim 2, wherein the controller controls the transfer portion to transfer the wafer to the measurement position or to the first position, based on the crystal orientation measurement result of the wafer.

11. The ion implantation apparatus according to claim 1, further comprising:
a crystal orientation measurement device at the measurement position; and
a sensor that detects a position of the crystal orientation measurement device.

12. The ion implantation apparatus according to claim 2, further comprising:
a crystal orientation measurement device at the measurement position; and
a sensor that detects a position of the crystal orientation measurement device.

13. The ion implantation apparatus according to claim 1, further comprising:
a process chamber including:
a platen;
a plurality of vacuum hands respectively having a plurality of gripping portions at distal ends of the vacuum hands; and
a plurality of loadlock chambers;
a chamber including a plurality of atmospheric robots; and
a plurality of cassettes,
wherein the measurement position is between the cassettes and the platen, and the second position is at the platen.

14. An ion implantation apparatus comprising:
a process chamber including:
a platen;
a plurality of vacuum hands respectively having a plurality of gripping portions at distal ends of the vacuum hands; and
a plurality of loadlock chambers;
a chamber including a plurality of atmospheric robots;
a plurality of cassettes; and
a controller that is configured to control the plurality of atmospheric robots, the plurality of loadlock chambers and the plurality of vacuum hands to transfer a wafer from one of the plurality of cassettes to a crystal orientation measurement position that is ion a transfer path between the one of the cassettes and the platen, and to start to move the wafer from the crystal orientation measurement position towards the platen before a crystal orientation measurement result of the wafer is output.

15. The ion implantation apparatus according to claim 14, wherein the controller controls to transfer another wafer to be processed next from the plurality of cassettes toward the crystal orientation measurement position before the crystal orientation measurement result of the wafer is output.

16. The ion implantation apparatus according to claim 14, further comprising an aligner that is configured to adjust a position of the wafer in a circumferential direction,
wherein the aligner is provided at the crystal orientation measurement position.

17. The ion implantation apparatus according to claim 16, wherein the aligner comprises an electrostatic chuck or a vacuum chuck.

18. An ion implantation apparatus comprising:
a process chamber including:
a platen;
a plurality of vacuum hands respectively having a plurality of gripping portions at distal ends of the vacuum hands; and
a plurality of loadlock chambers;
a chamber including an aligner that is configured to adjust a position of a wafer and a plurality of atmospheric robots;
a plurality of cassettes;
a transfer portion that includes one of the atmospheric robots, one of the loadlock chambers, and one of the vacuum hands, the transfer portion being configured to transfer a wafer along a transport path from one of the cassettes, to the aligner, and to the platen; and
a controller that is configured to control a crystal orientation measurement device to measure a crystal orientation of a wafer at the aligner and to control the transfer portion to start to move the wafer from the aligner towards the platen before a crystal orientation measurement result of the wafer is output from the crystal orientation measurement device.
